(19) United States
(12) Patent Application Publication
(10) Pub. No.: US 2021/0202132 A1
(43) Pub. Date: Jul. 1, 2021

(54) OXIDE SUPERCONDUCTING WIRE CONNECTION STRUCTURE

(71) Applicant: Fujikura Ltd., Tokyo (JP)

(72) Inventor: Naonori Nakamura, Sakura-shi (JP)

(73) Assignee: Fujikura Ltd., Tokyo (JP)

(21) Appl. No.: 16/754,909

(22) PCT Filed: Oct. 12, 2018
(86) PCT No.: PCT/JP2018/038105

§ 371 Date: Apr. 9, 2020

(30) Foreign Application Priority Data
Oct. 13, 2017 (JP) 2017-199283

(51) Int. Cl. H01B 12/06; H01L 39/12; H01R 4/68

(52) U.S. Cl. CPC H01B 12/06; H01R 4/68; H01L 39/12

(57) ABSTRACT

An oxide superconducting wire connection structure includes: connection target wires, each of which includes an oxide superconducting wire including a superconducting layer on a substrate; and connection superconducting wires that connects the connection target wires. The connection superconducting wires are narrower in width than the connection target wires. Current characteristics of the connection superconducting wires are equal to or greater than current characteristics of the connection target wires.

### CROSS-REFERENCE TO RELATED APPLICATIONS

This is a U.S. National Stage application of International Application No. PCT/JP2018/038105 filed Oct. 12, 2018, which claims priority from Japanese patent application No. 2017-199283 filed Oct. 13, 2017. These references are incorporated herein by reference in their entirety.

### TECHNICAL FIELD

The present invention relates to an oxide superconducting wire connection structure.

### BACKGROUND

Oxide superconducting wires are used as power supply cables, magnetic coils and the like because of their low current loss. Currently, since oxide superconducting wires are produced through a number of processes, it is difficult to produce a defect-free long wire for the above-mentioned usage. For this reason, the wire of the length for the above-mentioned usage is constituted by connecting a plurality of wires. In addition, in order to apply to a coil used for an MRI, an NMR, and the like among magnetic coils, both ends may be connected in a loop shape with a low resistance to enable operation in a permanent current mode. Patent Document 1 describes a connection structure in which a groove leading to the outside is provided in at least one of the superconducting wires.

In the case of the connection structure described in Patent Document 1, since oxygen is supplied through the groove during an oxygen annealing process, the groove needs to be continuously formed in the longitudinal direction. For this reason, the width of a superconducting layer becomes narrow and the current characteristics in a connection structure becomes lower than the current characteristics of the wire in portions other than a connection structure. As a result, the current characteristics in the connection structure is the upper limit of the current characteristics of the long wire obtained by connecting a plurality of wires.

The present invention is made in view of the above-mentioned circumstances, and provides a connection structure of an oxide superconducting wire which can improve the current characteristics in a connection structure.

### PATENT LITERATURE

[Patent Document 1] Japanese Unexamined Patent Application, First Publication No. 2016-201328

### SUMMARY

One or more embodiments of the present invention provide an oxide superconducting wire connection structure, in which connection target wires each including an oxide superconducting wire including a superconducting layer on a substrate are connected via connection superconducting wires narrower in width than the connection target wires; and current characteristics of the connection superconducting wires are equal to or greater than current characteristics of the connection target wires.

According to one or more embodiments of the present invention, two or more connection superconducting wires are arranged, and current characteristics obtained by summing current characteristics of two or more of the connection superconducting wires is equal to or greater than current characteristics of the connection target wire.

According to one or more embodiments of the present invention, a gap is provided so that two or more of the connection superconducting wires are non-contact in the width direction.

According to one or more embodiments of the present invention, the connection superconducting wire comprises an oxide superconducting wire including a superconducting layer on a substrate, and the superconducting layer has (1) a better crystal orientation than a superconducting layer of the connection target wire, (2) a film thickness is larger than a superconducting layer of a connection target wire, (3) an artificial crystal defect, or (4) a combination of two or more of the above-described (1) to (3).

According to one or more embodiments of the present invention described above, the current characteristics in the connection structure of the oxide superconducting wire can be improved.

### BRIEF DESCRIPTION OF THE DRAWINGS

FIG. 1 is a perspective view which shows a connection structure of an oxide superconducting wire according to one or more embodiments of the present invention.

FIG. 2 is a sectional view taken along the line II-II in FIG. 1.

### DETAILED DESCRIPTION

Hereinafter, based on one or more embodiments, the present invention will be described with reference to the drawings. The drawings are schematic diagrams, and the dimensional ratios of the respective components are not necessarily the same as the actual dimensional ratios.

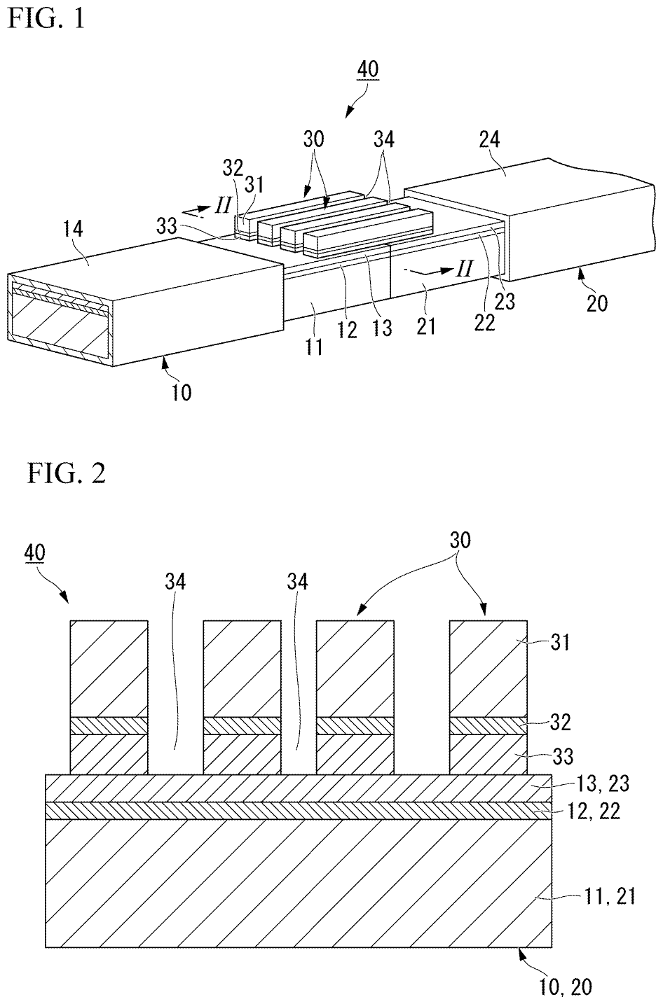

In FIG. 1, a perspective view of the connection structure according to one or more embodiments is shown. In FIG. 2, a cross-sectional view in a direction perpendicular to the longitudinal direction of the connection structure is shown.

The connection structure 40 has a structure in which two connection target wires 10 and 20 are connected via connection superconducting wires 30.

The connection target wires 10 has an oxide superconducting wire having superconducting layers 13 on the respective substrates 11. The connection target wires 20 has an oxide superconducting wire having superconducting layers 23 on the respective substrates 21. The connection target wires 10 has a laminated structure in which superconducting layer 13 is formed on one main surface of the substrates 11 via the intermediate layers 12. The connection target wires 20 has a laminated structure in which superconducting layer 23 is formed on one main surface of the substrates 21 via the intermediate layers 22.

In addition, the connection superconducting wire 30 according to one or more embodiments includes an oxide superconducting wire having a superconducting layer 33 on a substrate 31. The connection superconducting wire 30 has a laminated structure in which a superconducting layer 33 is formed on one main surface of a substrate 31 via an intermediate layer 32.

Protection layers 14 and 24 having metal or the like are formed around the connection target wires 10 and 20, respectively.

In the connection structure 40 according to one or more embodiments, the connection target wires 10 and 20 are arranged so that end portions in the longitudinal direction are opposed to each other in the longitudinal direction. The end portions in the longitudinal direction of the connection target wire 10 and 20 may be brought into contact with each other, or a gap may be provided between the end portions in the longitudinal direction of the connection target wire 10 and 20. On the main surfaces of the substrates 11 and 21, the direction intersecting the longitudinal direction is the width direction.

In the connection superconducting wire 30, the superconducting layer 33 is arranged so as to face and overlap the superconducting layers 13 and 23 of the respective connection target wires 10 and 20. As a result, the connection target wires 10 and 20 are connected via the connection superconducting wire 30. The superconducting layer 13 of the connection target wire 10 and the superconducting layer 33 of the connection superconducting wire 30, and the superconducting layer 23 of the connection target wire 20 and the superconducting layer 33 may be in contact or integrated so that superconducting connection is possible.

For this reason, a material having a greater electrical resistance than the superconducting layers 13, 23, and 33, such as solder, may not be interposed between the superconducting layer 13 of the connection target wire 10 and the superconducting layer 33 of the connection superconducting wire 30, and between the superconducting layer 23 of the connection target wire 20 and the superconducting layer 33.

The connection superconducting wire 30 is narrower than the connection target wires 10 and 20. Thereby, a portion of the superconducting layers 13 and 23 of the respective connection target wires 10, 20 is exposed without being covered with superconducting layer 33 of connection superconducting wire 30. In one or more embodiments, there are two or more connection superconducting wires 30, and a gap 34 is provided so that the connection superconducting wires 30 do not contact in the width direction (i.e. the connection super conducting wires 30 are separated in the width direction).

In the connection structure 40 according to one or more embodiments, the current characteristics of the connection superconducting wire 30 are equal to or greater than the current characteristics of the connection target wires 10 and 20. Thereby, the current characteristics of the connection structure 40 are not limited to the current characteristics of the connection superconducting wires 30, and become equal to or greater than the current characteristics of the connection target wires 10 and 20. Specific examples of current characteristics include critical current (Ic) below the critical magnetic field.

When two or more connection superconducting wires 30 are provided in parallel in the width direction, the current characteristics of each of the connection superconducting wires 30 may not be equal to or greater than the current characteristics of the connection target wires 10 and 20. The current characteristics obtained by adding two or more connection superconducting wires 30 may be equal to or greater than the current characteristics of the connection target wires 10 and 20.

When there is a difference in the current characteristics of the connection target wires 10 and 20, the current characteristics of the connection superconducting wire 30 may be at least equal to or greater than the lower current characteristics of the connection target wires 10 and 20. The current characteristics of the connection superconducting wire 30 may be equal to or greater than the average current characteristics of the connection target wires 10 and 20, or may be equal to or greater than the greater current characteristics of the connection target wires 10 and 20.

As a method of improving the current characteristics of the connection superconducting wire 30, for example, the following (1) to (3) or a combination of two or more of these can be provided.
(1) The superconducting layer 33 of the connection superconducting wire 30 has an oxide superconductor having a better crystal orientation as compared with the superconducting layers 13 and 23 of the respective connection target wires 10 and 20.
(2) The film thickness of the superconducting layer 33 of the connection superconducting wire 30 is thicker than the film thickness of the superconducting layers 13 and 23 of the respective connection target wires 10 and 20.
(3) The superconducting layer 33 of the connection superconducting wire 30 includes artificial crystal defects.

In the case (3), the superconducting layers 13 and 23 of the respective connection target wires 10 and 20 are not limited to the case where artificial crystal defects are not included, and the artificial crystal defects may be included. When all the superconducting layer 33 of the connection superconducting wire 30 and the superconducting layers 13 and 23 of the respective connection target wires 10 and 20 include the artificial crystal defects, due to a difference in the type or degree of the artificial crystal defects, the above-described (1), (2) or the like, a difference in current characteristics can be provided.

In the superconducting layer 33 of the connection superconducting wire 30, as an oxide superconductor having a good crystal orientation, for example, the orientation of the intermediate layer 32 of the connection superconducting wire 30 is greater than the intermediate layer 12 and 22 of the respective connection target wires 10 and 20. As the oxide superconductor constituting the superconducting layer 33 of the connection superconducting wire 30, a material having greater current characteristics than the oxide superconductor constituting the superconducting layers 13 and 23 of the respective connection target wires 10 and 20 may be used. The superconducting layers 13 and 23 of the respective connection target wires 10 and 20 may be a long and stable material, and the superconducting layer 33 of the connection superconducting wire 30 may be a short material having high current characteristics.

Examples of the artificial crystal defects include artificial pins made of different materials. Examples of the different materials used for introducing the artificial pin into the superconducting layer include one kind or two or more kinds of BaSnO₃(BSO), BaZrO₃(BZO), BaHfO₃(BHO), BaTiO₃ (BTO), SnO₂, TiO₂, ZrO₂, LaMnO₃, ZnO, and the like.

Next, the oxide superconducting wire constituting the connection target wires 10 and 20 and the connection superconducting wire 30 will be described.

The substrates 11, 21, and 31 are tape-shaped metal substrates. Each substrate has main surfaces on both sides in the thickness direction. Specific examples of the metal constituting each substrate include nickel alloys such as Hastelloy (registered trademark), stainless steel, and oriented NiW alloys in which a texture is introduced into the nickel alloy. The thickness of the substrate may be appropriately adjusted according to the purpose, and is, for example, in the range of 10 to 1000 μm.

The intermediate layer 12 is provided between the substrate 11 and the superconducting layer 13. The intermediate layer 22 is provided between the substrate 21 and the superconducting layer 23. The intermediate layer 32 is provided between the substrate 31 and the superconducting layer 33. The intermediate layer may have a multilayer structure, and may include, for example, a diffusion prevention layer, a bed layer, an alignment layer, a cap layer, and the like in order from the substrate side to the superconducting layer side. These layers are not necessarily provided one by one, and some layers may be omitted, or two or more of the same kind of layers may be laminated repeatedly.

The superconducting layers 13, 23, and 33 are constituted by an oxide superconductor. Examples of the oxide superconductor include a RE—Ba—Cu—O-based oxide superconductor represented by a general formula REBa₂Cu₃O7—x (RE123). Examples of the rare earth element RE include one kind or two or more kinds of Y, La, Ce, Pr, Nd, Sm, Eu, Gd, Tb, Dy, Ho, Er, Tm, Yb, and Lu. The thickness of the oxide superconducting layer is, for example, appropriately 0.5 to 5 μm.

The protection layers 14 and 24 have functions such as bypassing overcurrent and reducing a chemical reaction that occurs between the superconducting layers 13, 23, and 33 and the layers provided on the protection layers 14 and 24. Examples of the material of the protection layers 14 and 24 include silver (Ag), copper (Cu), gold (Au), an alloy of gold and silver, other silver alloys, copper alloys, and gold alloys. The thickness of the protection layers 14 and 24 is, for example, approximately 1 to 30 μm. When the protection layers 14 and 24 are thinned, the thickness may be 10 μm or less.

Two or more protection layers 14 and 24 can be laminated in the thickness direction. For example, silver or a silver alloy that can transmit oxygen under high temperature conditions is laminated as the protection layers 14 and 24 before the oxygen annealing, and copper or the like may be laminated on the silver or silver alloy after the oxygen annealing. After the oxygen annealing, a metal layer similar to the protection layers 14 and 24 may be provided around the connection target wires 10 and 20, respectively, or the connection superconducting wire 30 in the connection structure 40 to coat the superconducting layers 13, 23, and 33 and the like. A stabilization layer (not shown) or the like may be provided on the protection layers 14 and 24. Examples of the stabilization layer include a plating layer of metal such as Cu, Ag, Al, Sn, Ti, and an alloy, or a metal foil. The stabilization layer may be constituted by laminating the two or more kinds of the above.

As a manufacturing method of the connection structure 40, the connection target wire 10 having the intermediate layers 12 and the superconducting layer 13 on the substrate 11 is manufactured, and the connection target wire 20 having the intermediate layers 22 and the superconducting layer 23 on the substrate 21 is manufactured. After laminating the protection layers 14 and 24 around the respective connection target wires 10 and 20 including at least the upper surface of the superconducting layers 13 and 23, respectively, the superconducting layers 13 and 23 of the respective connection target wires 10 and 20 are connected via the superconducting layer 33 of the connection superconducting wire 30.

In the connection target wires 10 and 20 before the connection, when the protection layers 14 and 24 are formed on the respective superconducting layers 13 and 23 where the connection superconducting wire 30 is overlapped, at least a portion of the overlapped portion of the protection layers 14 and 24 may be removed.

After the superconducting layers 13 and 23 of the respective connection target wires 10 and 20 are overlapped on superconducting layer 33 of connection superconducting wire 30, the superconductor may be diffusion-bonded in order to reduce the electrical resistance at an interface. In addition, the deterioration of the superconducting layers 13, 23, and 33 may be recovered by performing oxygen annealing after the connection. In the diffusion bonding, the superconductors included in the opposing superconducting layers may be the same or similar materials. The ratio of the oxide to the metal element of the oxide superconductor can be optimized by the oxygen annealing.

If there is a gap 34 between two or more connection superconducting wires 30, oxygen can be circulated through the superconducting layers 13, 23 and 33 during the oxygen annealing after the connection. Even after the connection, the introduction of oxygen is not hindered, and the introduction of oxygen does not require a great deal of time. The oxygen annealing of the connection target wires 10 and 20 and the connection superconducting wire 30 may be performed at least once before or after the connection target wires 10 and 20 are connected to the connection superconducting wire 30. After connecting the wire with the superconducting layer exposed, a protection layer of silver or the like may be laminated on at least the exposed superconducting layer so that the superconducting layer is not exposed.

When there is a gap between the longitudinal ends of the connection target wires 10 and 20, or when there are gaps in two or more connection superconducting wires 30, a filler or the like (not shown) may be interposed in these gaps. Examples of the filler include metals, resins, and the like. When the superconducting layers 13 and 23 of the respective connection target wires 10 and 20 and the superconducting layer 33 of the connection superconducting wire 30 are superconductingly connected, even a conductor or an electrical insulator exists around the superconducting layers 13, 23 and 33, the superconducting properties of the wire are not affected.

As mentioned above, although the present invention has been described based on one or more embodiments, the present invention is not limited to the above-mentioned embodiments, and a various modifications are possible in the range which does not deviate from the summary of the present invention. Examples of the modifications include addition, replacement, omission, and other changes of components in one or more embodiments. Moreover, it is also possible to combine the component used for two or more embodiments appropriately.

When obtaining a wire in which two or more oxide superconducting wires are connected in the longitudinal direction via the connection portion, a long connection target wire and a short connection superconducting wire may be alternately and repeatedly connected.

To fabricate a superconducting coil using an oxide superconducting wire, for example, after a wire is wound around the outer peripheral surface of a winding frame to form a coil-shaped multilayer winding coil, the wire can be fixed by impregnating with a resin such as an epoxy resin so as to cover the wound wire. A plurality of coils may be arranged in the axial direction. In such a case, since each coil is adjacent in the width direction of the wire, both ends in the width direction of the connection superconducting wire may not protrude from both ends in the width direction of the connection target wire.

### EXAMPLES

Hereinafter, the present invention will be specifically described with reference to examples. Here, an example is shown in which a superconducting wire having a width of 4 mm is used as a connection target wire, and ends of the connection target wire are connected in a bridge shape by four connection superconducting wires. The electrical characteristics were measured at the liquid nitrogen temperature at which the wire became superconductive.
1. Fabrication of Connection Target Wire Used in Examples

(1-1) A substrate having Hastelloy (registered trademark) C-276 having a width of 12 mm, a length of 5 m, and a thickness of 0.75 mm (750 μm) was prepared as a substrate, and the main surface of the substrate was polished using alumina (A1203) particles having an average particle diameter of 3 μm.

(1-2) The substrate was degreased and washed with an organic solvent such as ethanol or acetone.

(1-3) An Al₂O₃ layer having a thickness of 100 nm was formed as a diffusion prevention layer on the main surface of the substrate by an ion beam sputtering method.

(1-4) A Y₂O₃ layer having a thickness of 30 nm was formed as a bed layer on the surface of the Al₂O₃ layer by an ion beam sputtering method.

(1-5) An MgO layer having a thickness of 5 to 10 nm was formed as an alignment layer on the surface of the Y₂O₃ layer by an ion beam assisted deposition method.

(1-6) A CeO₂ layer having a thickness of 500 nm was formed as a cap layer on the surface of the MgO layer by a pulse laser deposition method. An in-plane orientation degree (Δφ) of the CeO₂ layer was 4.0°.

(1-7) A GdBa₂Cu₃O_{7-X} layer having a thickness of 2 μm was formed as a superconducting layer on the surface of the CeO₂ layer by a pulse laser deposition method.

(1-8) An Ag layer having a thickness of 2 μm was formed as a protection layer by a DC sputtering method.

(1-9) The oxygen annealing was performed at 500° C. for 10 hours, and after the furnace cooling for 26 hours, the wire was taken out from the furnace.

(1-10) The wire was cut along the longitudinal direction with an infrared laser to obtain three connection target wires having a width of 4 mm. When the current characteristics of two of the wires were measured, the energizing current value (critical current value) at which two wires could be energized while maintaining the superconducting state was 200A.

(1-11) The Ag layer in a section of 7 cm in the longitudinal direction from one end of the two wires whose current characteristics were measured was dissolved to expose the superconducting layer, and then the ends were butted together.
2. Fabrication of Connection Superconducting Wire Used in Examples

(2-1) to (2-6) were carried out in the same manner as (1-1) to (1-6) described above.

(2-7) A GdBa₂Cu₃O_{7-X} layer having a thickness of 3.5 μm was formed as a superconducting layer on the surface of the CeO₂ layer by a pulse laser deposition method.

(2-8) to (2-9) were carried out in the same manner as (1-8) to (1-9) described above.

(2-10) The wire was cut along the longitudinal direction with an infrared laser to obtain seventeen superconducting wires having a width of 0.68 mm. When the current characteristics of one of the wires was measured, the energization current value was 61A.

(2-11) Four connection superconducting wires having a length of 5 cm were obtained from one wire whose current characteristics were measured. The Ag layer was dissolved over the entire length to expose the superconducting layer.
3. Connection of Superconducting Wires According to Examples

(3-1) As shown in FIG. 1, the superconducting layers 13 and 23 of the connection target wires 10 and 20 respectively and the superconducting layers 33 of the four connection superconducting wires 30 were face to each other, and were overlapped while being pressed in the thickness direction. The gaps of 200 μm or more were arranged so as not to contact between the connection superconducting wires 30 adjacent in the width direction. The gap 34 is not limited as described above as long as the flow of oxygen during oxygen annealing is not hindered.

(3-2) The facing portions of the connection target wire rods 10 and 20 and the connection superconducting wire rod 30 were arranged under a reduced pressure of 3×10⁻² Torr, and the superconducting layers 13, 23, and 33 were diffusion-bonded by irradiating an infrared laser from a side of the substrates 11 and 21 of the respective connection target wire rods 10 and 20. The laser irradiation conditions were a wavelength of 1064 nm, an energy density of 3×10⁵ W/cm², and an irradiation time of 10 seconds.

(3-3) After taking out the wire from under reduced pressure, 1 μm of Ag was deposited on the connection portion where the superconducting layer was exposed and on the connection portion.

(3-4) Oxygen annealing of the wire including the connection portion was performed at 500° C. for 10 hours, and after furnace cooling for 10 hours, the wire was taken out from the furnace.

(3-5) The energizing current value and the connection resistance of the wire including the connection portion were measured. The energizing current value of the wire including the connection portion was 200A, which was equivalent to 200A which was the energizing current value of the connection target wire before the connection. The connection resistance was 1 nΩ or less, indicating a superconducting state.
4. Connection of Superconducting Wire According to Comparative Example

(4-1) Connection target wires were prepared in the same manner as (1-1) to (1-11) in Examples.

(4-2) In order to prepare the connection superconducting wire of the comparative example, after fabricating the wire in the same manner as (1-1) to (1-10) of the connection target wire of the Example, the wire was cut into 30 cm lengths. Then, the superconducting layer on the substrate was divided into four in the width direction in a section of 5 cm which was 12.5 to 17.5 cm in the longitudinal direction from the end portion. The four-section dividing processing was performed by fabricating three grooves so that the substrate was not cut by scribe processing under the conditions of the wavelength of 532 nm, the frequency of 500 kHz, the output of 12 W, the pulse width of 10 ps, the processing speed of 300 mm/s, and repeating laser irradiation three times per groove. Each groove width was 50 μm. The energizing current value of the wire after the groove processing was 192A. After a scribe-processed 5-cm section was cut with an infrared CW laser, the Ag layer was dissolved to expose the superconducting layer to obtain a 5-cm long connection superconducting wire.

(4-3) Both ends of the connection superconducting wire scribe-processed with a length of 5 cm were opposed to the ends of the connection target wire, and were overlapped while being pressed in the thickness direction. Both opposing end portions were arranged under a reduced pressure of 3×10⁻² Torr, and the superconducting layer was diffusion-bonded by irradiating an infrared laser from a side of the substrate of the connection target wire. The laser irradiation conditions were the wavelength of 1064 nm, the energy density of 3×10⁵ W/cm², and an irradiation time of 10 seconds.

(4-4) After taking out the wire from under reduced pressure, 1 μm of Ag was deposited on the connection portion where the superconducting layer was exposed and on the connection portion.

(4-5) Oxygen annealing of the wire including the connection portion was performed at 500 ° C. for 10 hours, and after furnace cooling for 26 hours, the wire was taken out from the furnace.

(4-6) The energizing current value and the connection resistance of the wire including the connection portion were measured. The energizing current value of the wire including the connection portion was 192A, which was less than 200A, which was the energizing current value of the connection target wire before the connection. The connection resistance was 1 nΩ or less, indicating a superconducting state.

As described above, if the current characteristics of the connection target superconducting wire were equal to or greater than the current characteristics of the connection target wire, the energization current value of the wire including the connection portion was equal to the energization current value of the connection target wire before connection. Moreover, if the current characteristics of the connection target superconducting wire was lower than the current characteristics of the connection target wire, the energization current value of the wire including the connection portion was lower than the energization current value of the connection target wire before connection.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

10, 20: Connection target wire

### 11, 21, 31: Substrate

12, 22, 32: Intermediate layer
13, 23, 33: Superconducting layer
14, 24: Protection layer
30: Connection target superconducting wire

### 34: Gap

40: Connection structure

1. An oxide superconducting wire connection structure, comprising:
connection target wires, each of which comprises an oxide superconducting wire comprising a superconducting layer on a substrate; and
connection superconducting wires that connect the connection target wires, wherein
the connection superconducting wires are narrower in width than the connection target wires, and
current characteristics of the connection superconducting wires are equal to or greater than current characteristics of the connection target wires.

2. The oxide superconducting wire connection structure according to claim 1, wherein
current characteristics obtained by summing current characteristics of the connection superconducting wires is equal to or greater than current characteristics of the connection target wires.

3. The oxide superconducting wire connection structure according to claim 2, wherein the connection superconducting wires are separated in a width direction.

4. The oxide superconducting wire connection structure according to claim 1, wherein
each of the connection superconducting wires comprises an oxide superconducting wire comprising a superconducting layer on a substrate, and
the superconducting layer of each of the connection superconducting wires has one or more of: (1) a better crystal orientation than the superconducting layer of each of the connection target wires, (2) a film thickness larger than a film thickness of the superconducting layer of the connection target wires, and (3) an artificial crystal defect.
